(19) United States
(12) Patent Application Publication
(10) Pub. No.: US 2026/0242936 A1
(43) Pub. Date: Aug. 20, 2026

(54) METHOD FOR MANUFACTURING TRANSITION METAL DICHALCOGENIDE THIN FILM HAVING HIGHLY UNIFORM THREE-DIMENSIONAL HIERARCHICAL STRUCTURE

(71) Applicant: KOREA RESEARCH INSTITUTE OF STANDARDS AND SCIENCE, Daejeon (KR)

(72) Inventors: Sang Woo KANG, Daejeon (KR); Ji Hun MUN, Daejeon (KR); Jeong In SONG, Daejeon (KR)

(21) Appl. No.: 19/121,561

(22) PCT Filed: Jul. 4, 2023
(86) PCT No.: PCT/KR2023/009380

§ 371 Date: Apr. 16, 2025

(30) Foreign Application Priority Data
Jul. 13, 2022 (KR) 10-2022-0086109

(51) Int. Cl. C23C 16/30; C23C 16/02

(52) U.S. Cl. CPC C23C 16/305; C23C 16/0227

(57) ABSTRACT

The present invention relates to a method for manufacturing a highly uniform three-dimensional transition metal dichalcogenide thin film, and more specifically, to a method for manufacturing a transition dichalcogenide thin film having a highly uniform three-dimensional hierarchical structure in which impurities contained in a transition metal-containing precursor act as seeds.

### TECHNICAL FIELDS

The present invention relates to a method for manufacturing a transition dichalcogenide thin film having a highly uniform three-dimensional hierarchical structure in which impurities contained in a transition metal-containing precursor act as seeds.

### BACKGROUND ARTS

Transition Metal Dichalcogenides (TMDs) are materials with a plate-like structure similar to graphene, which consists of a single layer of three atomic layers and a layer of carbon atoms. Unlike graphene which has the characteristics of a semi-metal, transition metal dichalcogenides have the characteristics of n-type, p-type, or ambipolar semiconductors depending on the constituent material. In addition, because they are less than a few nanometers thick, they are highly versatile for use in flexible and transparent devices, making them promising materials in the field of nano-devices. However, large-area growth technology is essential for the research and industrial use of transition metal dichalcogenides. Until now, they have been mainly produced as two-dimensional thin films using chemical vapor deposition (CVD), physical vapor deposition (PVD), and atomic layer deposition (ALD).

Furthermore, since the adsorption of gas molecules occurs more actively at the edge site than at the basal plane, a vertical thin film is more advantageous than a horizontal thin film in electrochemical reaction applications. Therefore, the transition metal dichalcogenides with a three-dimensional structure can be applied to various electrochemical and catalytic reactions such as gas sensors, light sensors, batteries, and wettability coatings due to their high specific surface area and many edge sites. However, currently, transition metal dichalcogenides are mainly manufactured in the form of thin films with a two-dimensional planar structure (FIG. 1) or are formed only as simple three-dimensional structures in a direction perpendicular to the monolayer of the two-dimensional planar structure (FIG. 2).

The National R&D projects related to this task are as follows:
Task ID: 22011099
Task number: GP2022-0011-04
Ministry: Ministry of Science and ICT
Task management organization: Korea Research Institute of Standards and Science (KRISS)
Research project: Development of core measurement technology for future innovative industries
Research task: Mar. 1, 2003. Development of semiconductor measurement equipment technology
Contribution rate: 0.5
Task execution agency name: Korea Research Institute of Standards and Science (KRISS)
Research period: Jan. 1, 2022-12/31/2022
Task unique number: 22011241
Task number: GP2022-0003-07
Name of government department: Ministry of Science and ICT Name of the organization in charge of the project: Korea Research Institute of Standards and Science (KRISS)
Name of the research project: Establishing national measurement standards for international equivalence
Name of the research activity: Jan. 3, 1944. Root-taking support activity for young researchers, Jihoon Moon
Contribution rate: 0.5
Name of the organization in charge of the project: Korea Research Institute of Standards and Science (KRISS)
Research period: Jan. 1, 2022-31/12/2022

### PRIOR ART DOCUMENT

### Patent Document

Korea Registered Patent No. 10-1881304

### DETAILED DESCRIPTION OF THE INVENTION

### Technical Subjects

Therefore, the inventors completed the present invention by using the impurities contained in the precursor as a seed and manufacturing a transition metal dichalcogenide thin film with a highly uniform three-dimensional hierarchical structure by adjusting the precursor-to-reactant gas ratio and synthesis time.

Therefore, it is an object of the present invention to provide a method for manufacturing a transition dichalcogenide thin film having a highly uniform three-dimensional hierarchical structure in which impurities contained in a transition metal-containing precursor act as seeds.

### Technical Solution

To achieve the above-mentioned purpose, the present invention provides a method for manufacturing a three dimensional transition metal dichalcogenide thin film by comprising the steps of supplying a transition metal-containing precursor containing a chalcogen and impurities in a deposition chamber to generate a two-dimensional transition metal dichalcogenide planar layer and a three-dimensional hierarchical structure on a substrate.

In addition, the present invention provides a method for manufacturing a three dimensional transition metal dichalcogenide thin film under a temperature of 500° C. or less and a pressure of 0.001 Torr to 760 Torr, by comprising the steps of supplying a transition metal-containing precursor containing a chalcogen and impurities into a deposition chamber to generate a two-dimensional transition metal dichalcogenide planar layer and a three-dimensionally structured transition metal dichalcogenide thin film on a substrate for 30 minutes to 10 hours.

### Advantageous Effects

The transition metal dichalcogenide thin film with the highly uniform three-dimensional hierarchical structure of the present invention has a larger surface area than the transition metal dichalcogenide in the two-dimensional form and the vertical direction form, so it can be used in various applications such as sensors and electrochemical reactions that require surface reactions.

The present invention is also a very economical and time-efficient method in that the present invention uses a simple precursor and a change in the ratio of reacting gases to include impurities in the thin film without using additional seed materials, and is used to control the growth direction mechanism. Moreover, since it is very difficult to distribute the seed uniformly on the substrate to be synthesized, a very uniform three-dimensional hierarchical thin film can be synthesized using the method of utilizing impurities in the precursor as in the present invention.

### BRIEF DESCRIPTION OF THE DRAWINGS

FIG. 1 shows a schematic diagram of a conventional two-dimensional transition metal dichalcogenide thin film.

FIG. 2 shows a schematic diagram of a conventional two-dimensional planar and vertical directional simple three-dimensional transition metal dichalcogenide thin film.

FIGS. 3a to 3d show the manufacturing process of a transition metal dichalcogenide thin film with a three-dimensional hierarchical structure according to an exemplary embodiment of the present invention.

FIG. 4 is an image of a transition metal dichalcogenide thin film with a three-dimensional hierarchical structure according to an exemplary embodiment of the present invention.

FIG. 5 is a scanning electron microscope image of a transition metal dichalcogenide thin film having a three-dimensional hierarchical structure of the present invention.

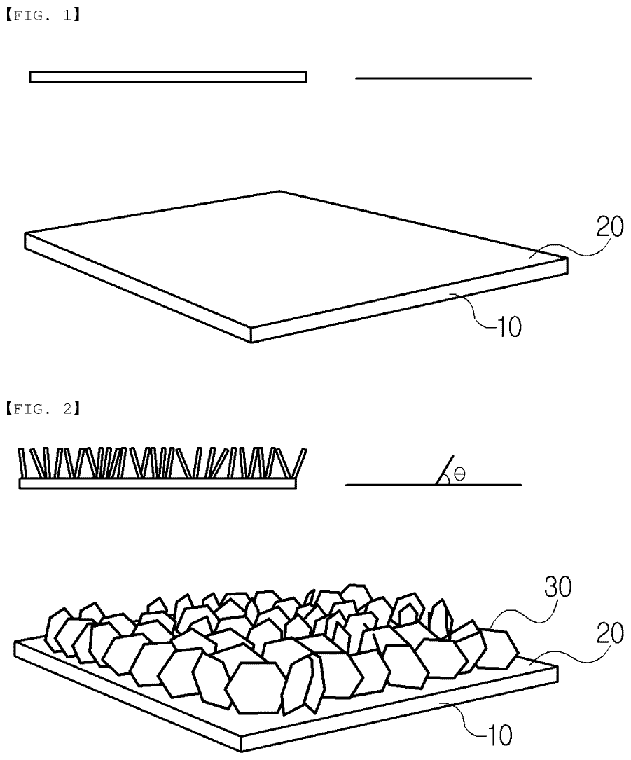

### BEST MODE

The following describes the present invention in detail so that a person with ordinary skill in the art to which the present invention belongs can easily carry it out by referring to the drawings attached thereto. However, the present invention can be implemented in various different forms and is not limited to the embodiments described herein. In addition, in order to clearly explain the present invention in the drawings, parts not related to the description have been omitted, and similar parts have been given similar drawing symbols throughout the specification.

Throughout the present specification, when a part is connected to another part, it includes not only direct connections but also electrical connections with other elements in between.

Throughout the present specification, when an element is located on another element, it includes not only when an element is adjacent to another element but also when another element exists between the two elements.

Throughout this specification, when a statement is made that a certain part contains a certain component, this means that, unless specifically stated to the contrary, the other components may be included rather than excluded.

Terms such as ‘approximately’, ‘substantially’, etc. used throughout the specification are used in the sense of the figures or figures close to them when the manufacturing and material tolerances inherent in the meaning of the figures are presented, and are used to prevent unscrupulous infringers from improperly using the disclosed contents with accurate or absolute figures to aid their understanding. The term ‘~ (doing) stage’, or ‘~ stage of’ used throughout the specification of the present invention does not mean ‘a step for ~’.

Throughout the present specification, the term combination(s) of these included in the expression in the Markush form means one or more mixtures or combinations selected from a group consisting of the components listed in the expression in the Markush form, and means including one or more selected from the group consisting of the above components.

Throughout the present specification, the reference to ‘A and/or B’ means ‘A, or B, or A and B’.

Hereinafter, preferred embodiments and the examples thereof are described in detail with reference to the accompanying drawings. However, the present invention may not be limited to these embodiments and examples and the drawings.

The present invention relates to a method for manufacturing a three-dimensional transition metal dichalcogenide thin film, which comprises supplying a transition metal-containing precursor containing a chalcogen and an impurity in a deposition chamber to deposit a two-dimensional transition metal dichalcogenide planar layer and a three-dimensional hierarchical structure on a substrate.

In addition, the present invention relates to a method for manufacturing a three dimensional transition metal dichalcogenide thin film, comprising the steps of supplying a transition metal-containing precursor containing a chalcogen and a transition metal-containing precusor including purities into a deposition chamber for 30 minutes to 10 hours at a temperature of 500° C. or less and a pressure of 0.001 Torr to 760 Torr to generate a two-dimensional transition metal dichalcogenide planar layer and a three-dimensionally hierarchical structure transition metal dichalcogenide thin film on a substrate.

The above method may include, but is not limited to, a step of reducing the surface energy of the substrate by surface treatment of the substrate prior to the deposition step. Reducing the surface energy of the substrate by surface treatment of the substrate is intended to enrich the nucleation sites on the substrate surface.

The number of nucleation sites on the surface of the substrate is a very important factor in forming highly uniform thin films, especially single-layer thin films. By controlling the surface energy of the substrate, the number of nucleation sites on the surface of the substrate can be controlled, and the number of these nucleation sites affects the crystal size of the two-dimensional transition metal dichalcogenide and the uniformity of the thin film.

Specifically, if there are few nucleation sites on the surface of the substrate, the resulting crystals of the transition metal dichalcogenide will be large in size, but the entire substrate will not be covered with a two-dimensional transition metal dichalcogenide thin film, and the uniformity of the thin film will be reduced. On the other hand, if there are abundant nucleation sites on the surface of the substrate, the crystals of the transition metal dichalcogenides are formed in small sizes, but the entire substrate can be covered with a two-dimensional transition metal dichalcogenide thin film, and the uniformity of the thin film is improved. The number of nucleation sites on the surface of such a substrate can be controlled by surface treatment of the substrate.

As an embodiment of the present invention, if an oxide-based insulator is used, selected from a group consisting of SiO₂, Al₂O₃, HfO₂, LiAlO₃, MgO, and combinations thereof, the hydroxyl group (—OH bond) present on the surface of the substrate is provided as a nucleation site, and the number of hydroxyl groups (—OH bonds) can be controlled by surface treatment of various substrates.

In order to increase the number of hydroxyl groups (—OH bonds) on the surface of the substrate to provide abundant nucleation sites, for example, a wet treatment method selected from a group consisting of a piranha solution treatment, a sulfuric acid (H₂SO₄) solution treatment, a hydrochloric acid (HCL) solution treatment, and an alkali metal hydroxide solution treatment; or a dry treatment method selected from a group consisting of an O₂ plasma treatment and a heat treatment using water vapor can be used to treat the surface of the substrate. The alkali metal hydroxide solutions may include potassium hydroxide solution and sodium hydroxide solution. The wet treatment method is not limited to the above, and any solution may be used as long as it can lower the surface energy of the oxide-based insulator substrate. In the preparation of the wet processing solution, the content of the solute in the solution is at least 0.0001% by weight, preferably 0.0001% by weight to the maximum solubility by weight (as the maximum solubility varies for each solute, the upper limit of the content may vary depending on the solute), but may be used in any ratio. In addition, the dry treatment method is not limited to the above, and any gas or molecule may be used as long as it can reduce the surface energy of the oxide-based insulator substrate.

In order to reduce the hydroxyl groups (—OH bonds) on the surface of the substrate to provide a rare nucleation growth sites, a method that can remove the hydroxyl groups (—OH bonds), for example, a treatment selected from a group consisting of vacuum heat treatment, annealing treatment, high-vacuum annealing treatment, and combinations thereof, but not limited to, can be performed. Any method that can remove the hydroxyl group (—OH bond) may be used. For example, if high-vacuum annealing is selected as the surface treatment method for an oxide-based insulator substrate, the number of nucleation sites can be suppressed by breaking the dangling bonds that provide reactive surface sites on the substrate through high-vacuum annealing. This may increase the size of the transition metal dichalcogenide crystals, but it may also reduce the uniformity of the two-dimensional transition metal dichalcogenide thin film.

The above description is limited to oxide-based insulator substrates, and in the case of crystalline substrates and metal substrates, the location of the surface defect may be provided as a nucleation site, and the surface defect provided as a nucleation site may be controlled by adjusting the surface energy through surface treatment of the substrate. In this case, too, the surface energy of the substrate can be reduced to enrich the nucleation (growth) sites.

In the present invention's method for manufacturing a transition metal dichalcogenide thin film, the surface energy of the substrate is reduced through surface treatment of the substrate, thereby enriching the nucleation (growth) sites and reducing the crystal size of the transition metal dichalcogenide, and consequently improving the uniformity of the two-dimensional transition metal dichalcogenide thin film.

The substrate may be selected from, but is not limited to, a group consisting of SiO₂, Al₂O₃, HfO₂, LiAlO₃, MgO, Si, Ge, GaN, AlN, GaP, InP, GaAs, SiC, glass, quartz, sapphire, graphite, graphene, plastic, polymer, hexagonal boron nitride (h-BN), and combinations thereof. The above-mentioned description may be desirable for a material that is inexpensive in terms of cost and advantageous for large areas, and it may be desirable to be able to control the number of nucleation (growth) sites by adjusting the surface energy.

The above impurities may act as seed elements for vertical and horizontal growth, and may be included in the above transition metal-containing precursor to cause differences in the decomposition rate of the precursor, without limitation. For example, the impurities may include carbon, oxygen, chlorine, copper, lead, zinc, cadmium, iron, etc. and may be, but are not limited to, CO₂. In the synthesis of conventional two-dimensional transition metal dichalcogenide thin films, for example, in the synthesis of pure MoS₂ thin films, since carbon and oxygen elements such as CO₂ contained in the transition metal-containing precursor act as impurities, a method was used in which additional reaction gases such as H₂ were injected to convert them into reactants such as H₄ and H₂O and then discharged so that they would not be bound to the thin film. However, in the present invention, such impurities may be used as seed elements for vertical and horizontal growth to control the growth direction mechanism of the thin film.

The chalcogen-containing precursors may be selected from the group consisting of H₂S, CS₂, SO₂, S₂, H₂Se, H₂Te, RISR₂ (where R₁ and R₂ are independently an alkyl group of carbon number 1 to 6, an alkenyl group of carbon number 2 to 6, or an alkyne group of carbon number 2 to 6), (NH₄)₂S, C₆HBOS, S(C₆H₄NH₂)₂, Na₂SH₂O and their combinations, and for example, may be an S-containing organic compound or S-containing inorganic compound selected from the group consisting of H₂S, CS₂, SO₂, S₂, R₁SR₂ (where R₁ and R₂ are independently an alkyl group of carbon number 1 to 6, alkenyl groups with a carbon number of 2 to 6, or alkynyl groups with a carbon number of 2 to 6), (NH₄)₂S, C₆H₈OS, S(C₆H₄NH₂)₂, Na₂SH₂O, and combinations thereof, but is not limited thereto.

As an embodiment of the present invention, a transition metal-containing precursor may include a transition metal selected from the group consisting of Ti, V, Cr, Mn, Fe, Co, Ni, Cu, Zn, Nb, Ta, Mo, W, Tc, Re, Ru, Os, Rh, Ir, Pt, Ag, Au, Cd, In, Tl, Sn, Pb, Sb, Bi, Zr, Te, Pd, Hf and their combinations, but is not limited thereto. For example, the transition metal-containing precursor may include a selection from the group consisting of Mo(CO)₆, Mo(Cl)₅, MoO(Cl)₄, MoO₃, and their combinations, but is not limited thereto.

The ratio of the transition metal-containing precursor to the chalcogen-containing precursor may vary depending on the type of precursor used, for example, it may be 1:1 to 20, but is not limited to this. Specifically, if Mo(CO)₆ is used as the transition metal-containing precursor and H₂S is used as the chalcogen-containing precursor, Mo(CO)₆: When the ratio of Mo(CO)₆:H₂S is 1:20 or less, the above impurities remain on the surface of the grown thin film to the extent that they can be left behind. When the ratio exceeds 1:20, carbon and oxygen (oxide) react with hydrogen or sulfur contained in H₂S to form volatile compounds such as CH₄ and H₂O, making it difficult for them to remain on the surface.

The deposition may be performed for 30 minutes to 10 hours, for example, 40 minutes to 6 hours, but is not limited thereto. If the deposition time exceeds 10 hours, other structures, such as a radial structure rather than a hierarchical structure, may be formed by other impurities, but this is not limited thereto.

The deposition step described above may be performed using any deposition method known in the art without any particular restriction, and for example, it may be performed using the chemical vapor deposition (CVD) method, but it is not limited to this. For example, the above-mentioned chemical vapor deposition method may include low pressure chemical vapor deposition (LPCVD), atmospheric pressure chemical vapor deposition (APCVD), metal organic chemical vapor deposition (MOCVD), plasma enhanced chemical vapor deposition (PECVD), inductively coupled plasma-chemical vapor deposition (ICP-CVD), atomic layer deposition, or plasma atomic layer deposition, but it is not limited thereto.

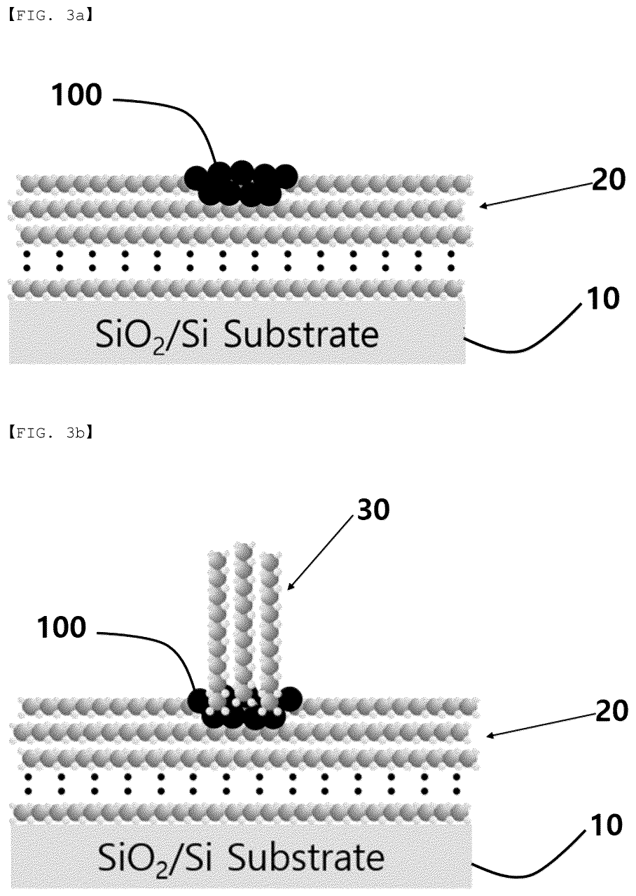

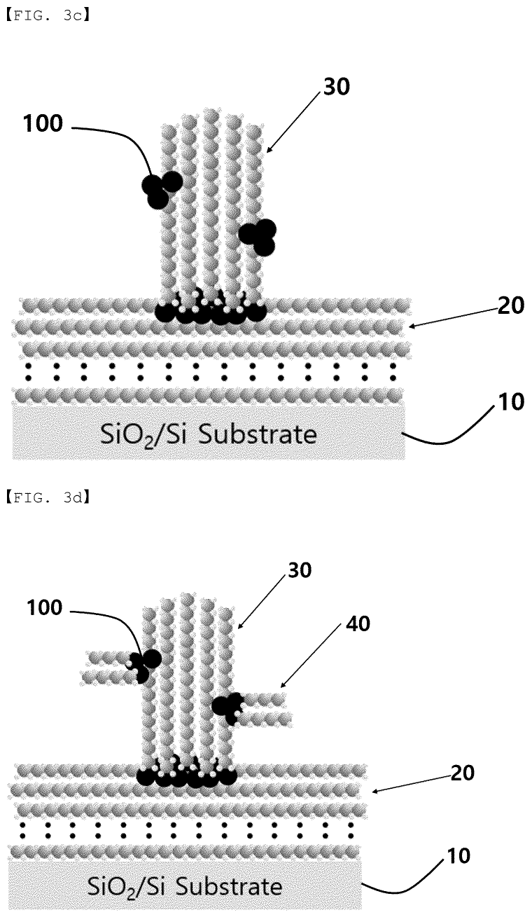

FIGS. 3a to 3d show the manufacturing process of a transition metal dichalcogenide thin film having a three-dimensional hierarchical structure according to one embodiment of the present invention, and the manufacturing process will be described with reference to these figures.

The manufacturing process of the present invention may include the following steps:
(1) a step of forming a two-dimensional transition metal dichalcogenide planar layer (20) containing impurities (100) on the substrate (10) (FIG. 3a);
(2) a step in which the decomposition rate of the transition metal-containing precursor and the chalcogen-containing precursor at the position of the two-dimensional planar transition metal dichalcogenide planar layer (20) containing impurities is accelerated, thereby growing a thin film (30) in a vertical direction (FIGS. 3b); and
(3) a step in which a three-dimensional hierarchical structure of a thin film (40) is formed by accelerating the decomposition of a transition metal-containing precursor and a chalcogen-containing precursor by impurities (100) contained in the thin film grown in the above-mentioned vertical direction (FIGS. 3c and 3d).

In the above (1) step, the above impurities are included in the thin film in real time at the initial stage of the synthesis process, thereby forming a thin planar layer thin film (200) containing the impurities (100) (FIG. 3a). The above impurities (100) may be doped or may also be included in the form of carbon compounds in the thin film, but are not limited thereto.

In this way, the decomposition rate of the precursor is accelerated at the location of the planar layer film (20) containing impurities (100), and the thin film (30) grows in the vertical direction due to the fast decomposition rate of the precursor (FIG. 3b).

Then, as the synthesis time increases, the thin film grown in the vertical direction begins to contain precursor impurities (100) (FIG. 3c). The decomposition rate of the precursor is accelerated by the impurities (100) contained within the thin film that has grown in the vertical direction, resulting in the formation of a thin film (40) with a horizontal or branched hierarchical structure (FIG. 3d).

Due to the difference in the decomposition rate of the precursor and thin film growth speed between a thin film containing impurities (100) and a pure thin film that does not contain impurities, it is possible to synthesize a transition metal dichalcogenide thin film having a three-dimensional structure that includes not only a two-dimensional plane+vertical direction, but also a horizontal or branch structure.

### EXEMPLARY EMBODIMENT

The following embodiments provide a more detailed description of the present invention through the embodiments of the present invention, but these embodiments are only examples to help understand the present invention, and the scope of the present invention is not limited by the following embodiments.

### Exemplary Embodiment 1

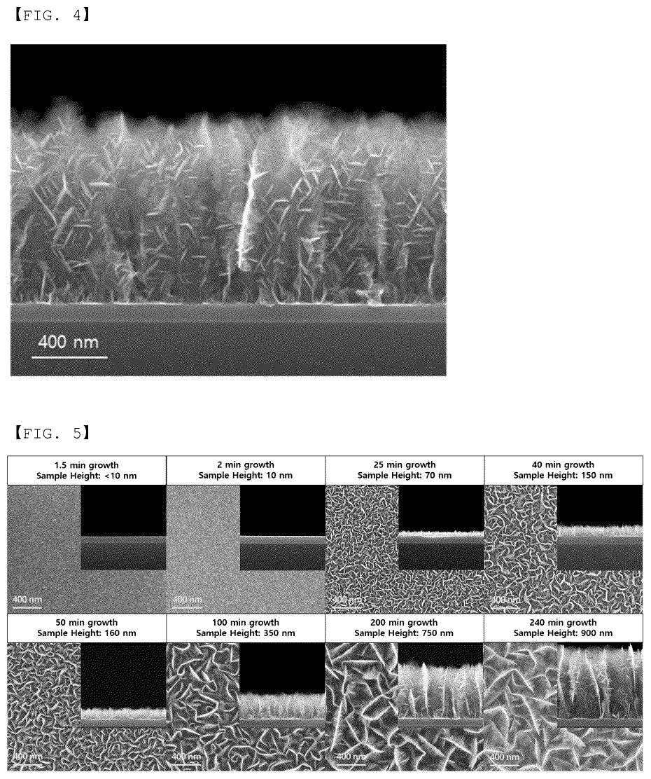

A p-type silicon wafer (SiO₂/Si, 1-10 Ω·cm) of 100 nm-thick SiO₂ was used as a synthetic substrate. The substrate was pre-cleaned and placed on a silicon carbide (Sic)-coated susceptor in a load-lock chamber within a short period of time to prevent any contamination from the surrounding environment. After that, the surface of the substrate was treated with KOH (KOH, 99.99%, Sigma-Aldrich, USA) solution to reduce the surface energy of the substrate. Next, high-purity H₂S (99.9%, Noble gas, Republic of Korea) as a chalcogen-containing precursor and Mo(CO)₆ (98%, Sigma Aldrich) as a precursor containing transition metals were supplied into the chamber to perform a synthesis in a reactor by way of showerhead-type metal organic chemical vapor deposition (MOCVD) at a temperature of 250° C. and a pressure of 260 mTorr to thereby synthesize a MoS₂ thin film, which is a three-dimensional transition metal dichalcogenide thin film. The synthesized MOS2 thin film exhibited a three-dimensional hierarchical structure, as shown in FIG. 4.

The process of forming a three-dimensional hierarchical structure according to the synthesis time was observed with a scanning electron microscope, and the results are shown in FIG. 5. The concentration change of impurities (carbon) according to each synthesis time was measured by X-ray photoelectron spectroscopy, and the results are shown in Table 1.

As shown in FIG. 5, within 40 minutes of the start of synthesis, a transition metal dichalcogenide thin film with a two-dimensional+three-dimensional structure in the vertical direction n was formed, and its height was 150 nm. A three-dimensional hierarchical structure of thin film was formed after 40 minutes or more of synthesis. The height of the three-dimensional hierarchical structure of thin film was 900 nm at 240 minutes of synthesis.

TABLE 1

| growth time | sample height | Atomic compositions (%) | | | | |
|---|---|---|---|---|---|---|
| (min) | (nm) | O1s | C1s | Mo3d | S2p | Si2p |
| 1.5 | <10 | 48.22 | 13.31 | 3.12 | 5.93 | 29.41 |
| 2 | 10 | 41.82 | 16.6 | 5.45 | 9.56 | 26.58 |
| 25 | 70 | 4.14 | 21.73 | 21.99 | 50.96 | 1.18 |
| 40 | 150 | 3.6 | 21.03 | 23.53 | 51.84 | |
| 50 | 160 | 3.03 | 15.39 | 24.83 | 56.75 | |
| 100 | 350 | 0.72 | 9.59 | 27.4 | 62.3 | |
| 200 | 750 | | 7.82 | 27.97 | 64.21 | |
| 240 | 900 | 1.97 | 8.5 | 27.88 | 61.65 | |

Referring to FIG. 5 and Table 1 above, it can be seen that the 1.5-minute growth sample and the 2-minute growth sample are in the process of forming the initial two-dimensional thin film. During the process of forming a two-dimensional thin film, carbon, which allows the vertical direction thin film to grow, is included in the thin film in real time, so the carbon content increased from 13.31% to 16.6%.

The process of forming a transition metal dichalcogenide thin film of a two-dimensional+vertical direction three-dimensional structure from the initial two-minute growth to the 40-minute growth sample includes a step of containing a precursor impurity that enables a hierarchical structure thin film to be grown on a vertically grown thin film. Therefore, it can be confirmed that the carbon content increased by 21.03% compared to the carbon content of the two-minute growth sample.

From the 50-minute growth sample, where the three-dimensional hierarchical thin film is formed, the number of three-dimensional hierarchical thin films increased as the synthesis time increased, and the carbon content tended to decrease to 15.39%, 9.59%, 7.82%, and 8.5%, respectively. This is because the three-dimensional hierarchical thin film contains less impurities (carbon) that serve as a vertical growth seed compared to two-dimensional thin films and three-dimensional thin films in the vertical direction, and the above results were observed as the synthesis time increased.

Although the above describes the preferred embodiment of the present invention in detail, the scope of the present invention is not limited to this, and various variations and improved forms of the present invention by those skilled in the art using the basic concepts defined in the following claims are also within the scope of the present invention.

1. A method for manufacturing a three-dimensional transition metal dichalcogenide thin film, comprising supplying a chalcogen-containing precursor and an impurity-containing transition metal-containing precursor in a deposition chamber to deposit a two-dimensional transition metal dichalcogenide planar layer and a three-dimensional hierarchical structure on the substrate.

2. The method of claim 1, further comprising a step of reducing the surface energy of a substrate by treating the surface of the substrate prior to the deposition step.

3. The method of claim 1, wherein the impurities include elements selected from a group consisting of carbon, oxygen, chlorine, copper, lead, zinc, cadmium, iron and combinations thereof.

4. The method of claim 1, wherein the impurities act as seed elements for the formation of a three-dimensional structure.

5. The method of claim 1, wherein the chalcogen-containing precursor is an S-containing organic compound or an S-containing inorganic compound.

6. The method of claim 1, wherein the transition metal-containing precursor comprises a transition metal selected from a group consisting of Ti, V, Cr, Mn, Fe, Co, Ni, Cu, Zn, Nb, Ta, Mo, W, Tc, Re, Ru, Os, Rh, Ir, Pt, Ag, Au, Cd, In, Tl, Sn, Pb, Sb, Bi, Zr, Te, Pd, Hf and combinations thereof.

7. The method of claim 1, wherein the substrate is selected from a group consisting of SiO2, Al2O3, HfO2, LiAlO3, MgO, Si, Ge, GaN, AlN, GaP, InP, GaAs, SiC, glass, quartz, sapphire, graphite, graphene, plastic, polymer, boron nitride (h-BN), and combinations thereof.

8. The method of claim 1, wherein the ratio between the transition metal-containing precursor and the chalcogen-containing precursor is 1:1 to 20.

9. The method of claim 1, wherein the deposition is performed for 30 minutes to 10 hours.

10. The method of claim 1, wherein the deposition step includes steps of:
forming a two-dimensional planar transition metal dichalcogenide planar layer on the substrate;
growing a thin film in a vertical direction at a location of the two-dimensional planar transition metal dichalcogenide planar layer containing impurities at a faster decomposition rate of the transition metal-containing precursor and the chalcogen-containing precursor; and
forming a three-dimensional hierarchical structure of a thin film by accelerating the decomposition speed of a transition metal-containing precursor and a chalcogen-containing precursor by impurities contained thin film grown in the vertical direction.

11. The method of claim 2, wherein surface treatment of the substrate is performed by a wet treatment method selected from a group consisting of a piranha solution treatment, a sulfuric acid (H2SO4) solution treatment, a hydrochloric acid (HCL) solution treatment, and an alkali metal hydroxide solution treatment; or a dry treatment method selected from a group consisting of an O2 plasma treatment and a heat treatment using water vapor.

12. The method of claim 1, wherein the deposition step is performed at a temperature of 500° C. or lower.

13. The method of claim 1, wherein the deposition step is performed using the chemical vapour deposition (CVD) method.

14. A method for manufacturing a three-dimensional transition metal dichalcogenide thin film, comprising generating a two-dimensional transition metal dichalcogenide planar layer and a three-dimensionally hierarchical structure of a transition metal dichalcogenide thin film on the substrate for 30 minutes to 10 hours by supplying a chalcogen-containing precursor and a impurity-containing transition metal-containing precursor within a deposition chamber under a temperature of 500° C. or less and a pressure of 0.001 Torr to 760 Torr.

15. The method of claim 14, wherein the ratio between the transition metal-containing precursor partial pressure and the chalcogen-containing precursor partial pressure is 1:1 to 20.
